(19) United States
(12) Patent Application Publication
(10) Pub. No.: US 2007/0228386 A1
(43) Pub. Date: Oct. 4, 2007

(54) Wire-bonding free packaging structure of light emitted diode

(76) Inventors: Jin-Shown Shie, Hsinchu City (TW); C.Y. Hsieh, Hsinchu City (TW); Chien Chung Lin, Jhudong Township (TW)

Correspondence Address: PERKINS COIE LLP, P.O. BOX 2168, MENLO PARK, CA, 94026, US

(21) Appl. No.: 11/396,383

(22) Filed: Mar. 30, 2006

(51) Int. Cl. H01L 33/00

(52) U.S. Cl. 257/79

(57) ABSTRACT

A wire-bonding free packaging structure for light emitting diode (LED) is provided. Prepare a silicon sub-mount having a backside bulk micromachining reach-through U-shape cavity for accommodating a flip-chip LED. This stack-integrated packaging module with solder bumps on the surface is than bonded to an aluminum PC board with flip-chip surface mount packaging or bump technology. This gives very good heat conduction to the heat sink of the PC board and can endure more current to enhance light intensity of the LED. This stack-integrated packaging module can also be bonded on a lead frame with two leg packaging, which can also increase heat conduction.

### BACKGROUND OF THE INVENTION

1. Field of the Invention

The present invention relates to a packaging structure of light emitting diode (LED). In particular, relates to a wire-bonding free packaging structure for LED mounted into a sub-mount.

2. Description of the Related Art

As a good light source and device made by III-V or II-VI semiconductor material, LEDs possesses advantages of small size, long life time, low driving voltage, rapid response and good oscillation-proof, etc.

By changing the semiconductor materials and device structure of LEDs, different visible and invisible light can be achieved, wherein AlGaAs, InGaAlP and InGaN are suitable for producing LEDs with high luminance of more than 1000 mcd.

In order to increase the light intensity of a LED, the compound materials used has widely studied, also the structure of the device can be modified such as Double Hetero Junction (DH), quantum well (QW) or multi-quantum wells (MQW), etc., the intensity has increased more than 1 order these years, hence the application area of LED is more and more, from indicator to traffic signal, light source of LED printer head, LED display, even LED illumination. However, the light intensity is limited to junction breakdown, which is mostly due to over heating of the junction. It results that heat transfer becomes very important for enhancing light intensity of a LED.

Package structure has affected strongly on heat transfer of a LED. It is commonly bonding the LED chip on a lead frame by die bonding, then connect the positive and negative electrode to the positive and negative legs, respectively. It results not only the route of heat transfer is too long, but also the conduction area of the gold wire is too small, thus results very bad heat transfer. In operation, the maximum endure current is choose to balance the heat produced by operation and the heat transfer. This maximum current limits the maximum light intensity. This is the cause that LED is still difficult to be used in illumination, such as the head light of a car, room illumination, etc. Thus it is still need a LED light source to replace the electric light bulb or fluorescent lamp with high energy consumption.

It is then further need to improve the brightness or light intensity other than discovering of new materials or active area structure of LED device, package technique is also an important area. How to improve the heat transfer of LED packaging, such that the current of operation can be increased and would not cause breakdown or burn out of the PN junction, so that the light intensity may improve and the brightness may increase with the same LED device structure and material used.

Therefore there exists a need to improve significantly the packaging technique, so that the heat transfer capability can be improved to increase the light intensity. The present invention will give a solution to meet this requirement.

### SUMMARY OF THE INVENTION

The object of the present invention is to provide a wire-bonding free packaging structure for light emitting diode (LED). A silicon sub mount with a reach-through U-shape cavity is used to accommodate a flip-chip LED, and form a stack-integrated packaging module with solder bump on the surface, the module is then bonded to an aluminum PC board with flip-chip surface mount packaging technology, thus the LED will have very good heat transfer and the light intensity will be enhanced.

Another object of the present invention is to provide a wire-bonding free packaging structure for light emitting diode (LED). A silicon sub mount with a reach-through U-shape cavity is used to accommodate a flip-chip LED, and form a stack-integrated packaging module with solder bump on the surface, the module is then bonded to a common lead frame with flip-chip surface mount packaging technology, thus the LED will have good heat transfer and the light intensity will be enhanced.

In order to achieve the above objects, a first aspect of the present invention teaches a packaging structure of light emitting diode (LED), the LED chip is bonding into the U-shape cavity of a silicon sub-mount by flip-chip bonding to form a cascaded packaging module, this module is then packaged by flip-chip surface mount on an aluminum PC board with heat-sink, This including a silicon sub-mount, forming solder bumps of positive and negative electrode on the front side; then by etching to form a reach-through U-shape cavity on the back-side to accommodate the LED chip. A positive electrode, a negative electrode, and reflective metals are evaporated with a native mask; A light emitting diode (LED) chip, can be any chip produced by a conventional technology, having a substrate, an active light emitting area, a positive and a negative electrode on the front-side is used to form the module. A PC board, having an anodic oxide layer, a printed circuit, and a heat-sink device, is used to bond the module. The LED chip is bonding into the silicon sub-mount by flip-chip die-bonding, the positive and negative electrodes of the LED chip are aligned to the positive and negative electrodes of the silicon sub-mount, respectively, to form a cascaded packaging module. Then bonds the cascaded packaging module to the PC board by flip-chip surface mount, and finally forms a micro lens on the surface of the LED.

### BRIEF DESCRIPTION OF THE DRAWINGS

FIG. 1 (A) is the step of forming an align mark and contact via holes in cross sectional view.

FIG. 1 (B) is a cross sectional view of the steps for forming solder bumps.

FIG. 1 (C) is a cross sectional view of the step for forming a U-shape cavity.

FIG. 1 (D) is an example of a third mask.

FIG. 1 (E) is another example of a third mask.

FIG. 1 (F) is a cross sectional view of the step for performing aluminum evaporation.

FIG. 1 (G) is a cross sectional view of the silicon sub-mount after evaporation.

FIG. 2 is a cross sectional view of the LED chip.

FIG. 3 (A) is a cross sectional view of a hybrid packaging module after bonding the LED chip into the U-shape cavity of the silicon sub-mount by flip-chip packaging.

FIG. 3 (B) is the relative position between the positive and negative metal electrodes of the silicon sub-mount and the positive and negative electrodes of the LED chip in accordance with one embodiment of the present invention.

FIG. 3 (C) is the relative position between the positive and negative metal electrodes of the silicon sub-mount and the positive and negative electrodes of the LED chip in accordance with another embodiment of the present invention.

FIG. 4 is a cross sectional view of forming a focus lens with transparent polymer material.

FIG. 5 is a cross sectional view of flip-chip bonding the module of the LED chip and the silicon sub-mount to an aluminum PC board.

FIG. 6 is a cross sectional view of flip-chip bonding the module of the LED chip and the silicon sub-mount to an ordinary PC board.

FIG. 7 shows the structure of a display in according to one embodiment of the present invention.

### DETAILED DESCRIPTION OF THE INVENTION

The foregoing and other advantages of the invention will be more fully understood with reference to the description of the best embodiment and the drawing as followed description.

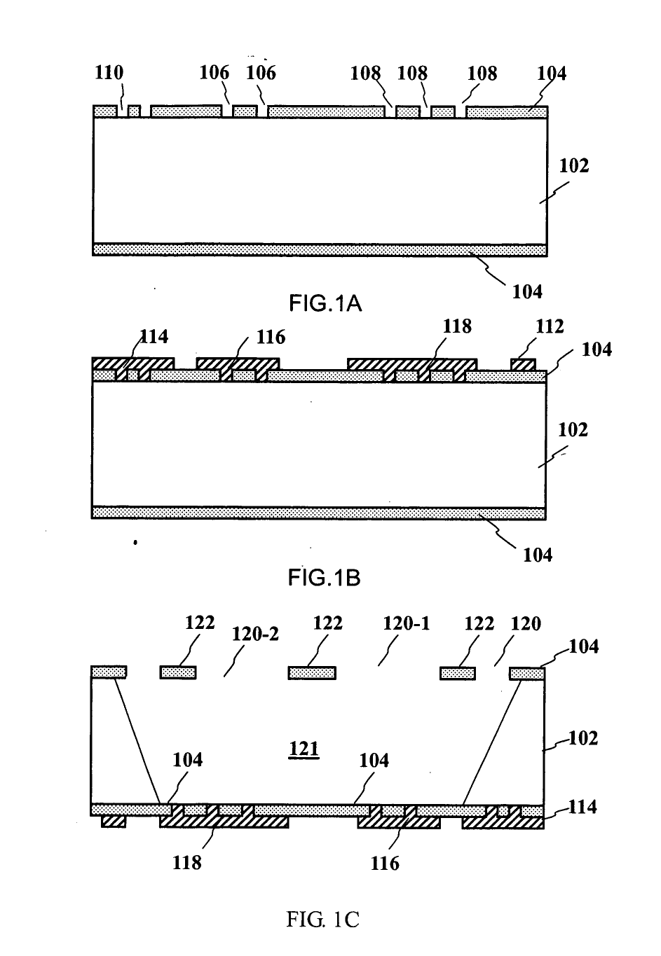

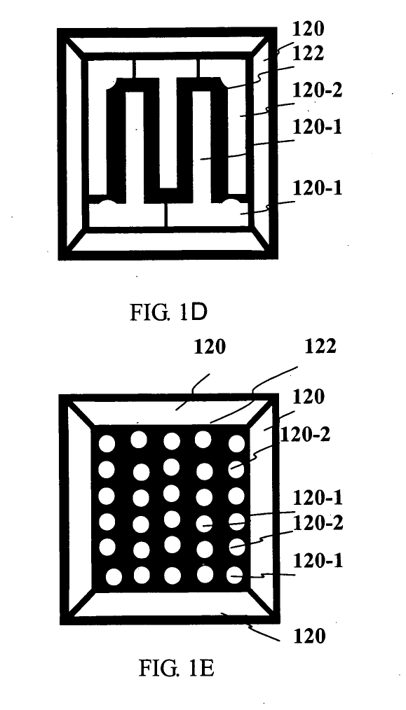

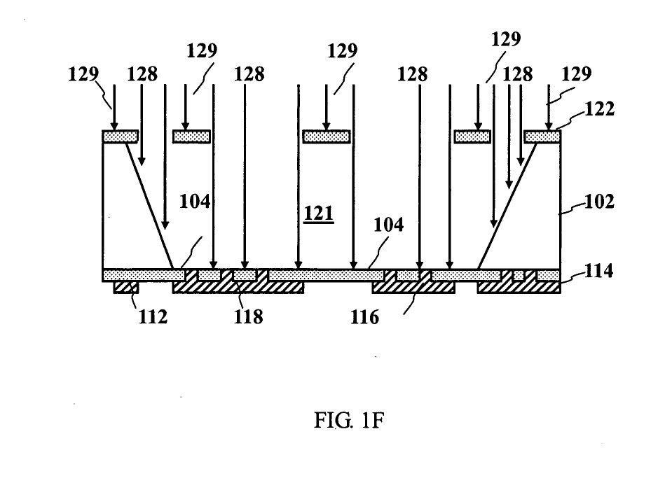

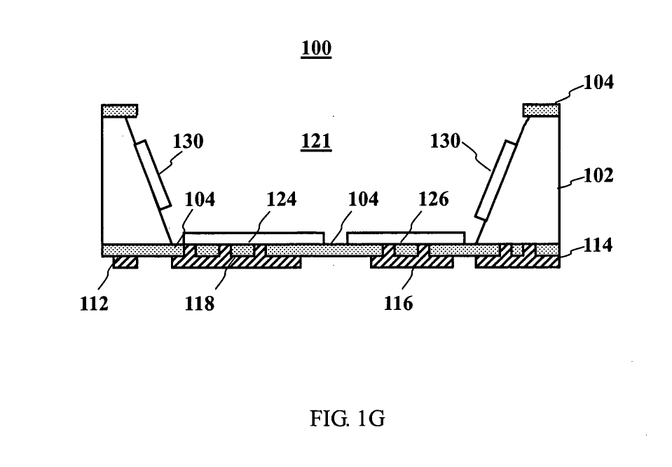

The manufacturing procedure of the packaging structure in according to the present invention can be understood by referring to FIG. 1 through FIG. 7. FIG. 1 illustrates the manufacturing steps of a silicon sub-mount in according to one embodiment of the present invention. First, as shown in FIG. 1 (A), FIG. 1 (A) is the step of forming an align mark and contact via holes in cross sectional view. Prepare the p-type silicon wafer 102 which is (100) orientation, any doping, even a reclaimed substrate. A layer of silicon nitride 104 is deposited on both sides of the wafer by LPCVD. On the front side, a first mask is used in lithography to form a negative via hole 106, a positive via hole 108 and an align mark for the stepper. Refer to FIG. 1 (B). FIG. 1 (B) is a cross sectional view of the step for forming solder bumps. A negative solder bump 116, a positive solder bump 118, a seal 114 of the align mark 110 for the stepper and a back side align mark (BSA) 112 are formed by using a second mask in lithography and etching, or by electroplating copper/tin. Refer to FIG. 1 (C). FIG. 1 (C) is a cross sectional view of the step for forming a U-shape cavity. An etch-window 120, a window for negative electrode area 120-1, a window for positive electrode area 120-2 is opened by using a third mask in lithography and etching for the next step to perform reach-through etching and form a U-shape cavity. Now a native shadow mask 122 is remained to form an isolation mask in deposition of aluminum metal, thus avoid an etching step. Then perform an anisotropic bulk micromachining etching to form a reach-through U-shape cavity 121 in the silicon wafer. This U-shape cavity 121 will be used to accommodate a LED chip. Now the silicon nitride layer 104 on the front side of the silicon wafer forms a membrane to support the solder bumps 116 and 118. The silicon nitride layer of the native shadow mask 122 on the rear side of the silicon wafer forms a membrane to be a mask in deposition of aluminum. FIG. 1 (D) is an example of a third mask. This mask has a native shadow mask 122, reflection metal area 120, negative electrode area 120-1 and positive electrode area 120-2. FIG. 1 (E) is another example of a third mask. This mask has a native shadow mask 122, reflection metal area 120, a round shaped negative electrode area 120-1 and a round shaped positive electrode area 120-2. The round shaped electrodes are used to form a cylinder negative electrode and a cylinder positive electrode to eliminate the effect of thermal expansion on the package. Refer to FIG. 1 (F). FIG. 1 (F) is a cross sectional view of the step for performing aluminum evaporation. The evaporation is preferred for E-gun evaporation and can not use sputtering or chemical vapor deposition, otherwise cross deposition will cause the electrodes connected together and isolation will fail. E-gun evaporation is a point source. The direction of evaporation is 128 only and form isolated positive electrode 124, negative electrode 126 and a reflection metal mirror 130, no other direction. The evaporated aluminum 129 will stay on the shadow mask 122, under the shadow area of the native shadow mask 122 would not evaporate and no aluminum there. As shown in FIG. 1 (G), FIG. 1 (G) is a cross sectional view of the silicon sub-mount after evaporation. A reflection metal mirror 130 is formed under the reflection metal area 120 of the third mask, a negative electrode 124 is formed under the negative electrode area 120-1 of the third mask, a positive electrode 126 is formed under the positive electrode area 120-2 of the third mask, an isolation 104 is formed under the native shadow mask 122 of the third mask. After evaporation, the native shadow mask 122 can be removed by mechanical method. The silicon sub-mount 100 with U-shape cavity for accommodating a LED chip is then completed.

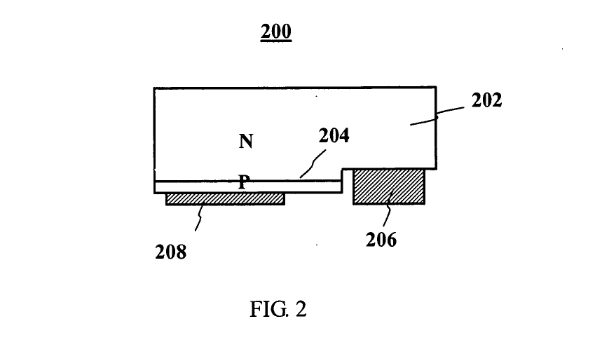

Refer to FIG. 2. FIG. 2 is a cross sectional view of the LED chip. The LED chip such as red, blue, green or other color LED is produced by a traditional technique. The substrate of a LED chip 200 is sapphire or other substrate like GaAs. There is an active light emitting area form by a PN junction or quantum well. A positive electrode 208 is formed on the P-type layer. A negative electrode 206 is formed on the N-type layer with the P-type material removed by etching. Thus form a flip-chip condition.

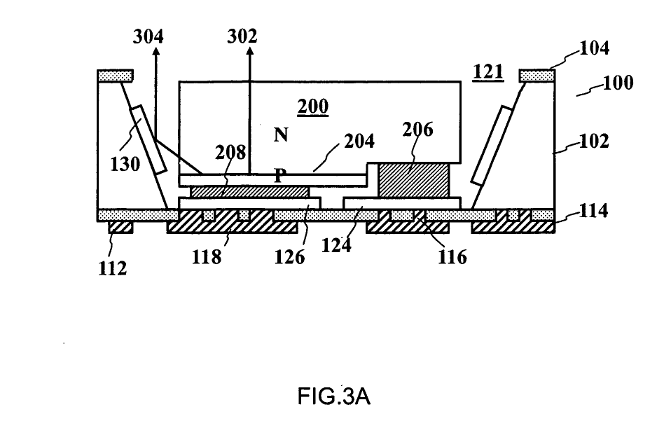

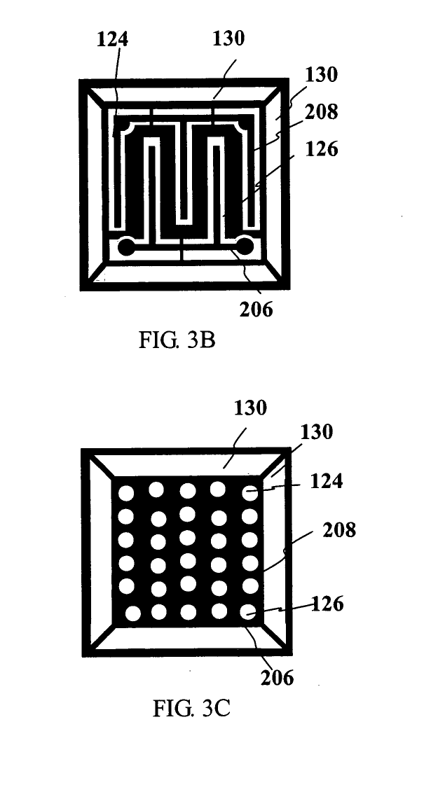

Refer to FIG. 3 (A). FIG. 3 (A) is a cross sectional view of a hybrid packaging module after bonding the LED chip into the U-shape cavity of the silicon sub-mount by flip-chip packaging. Upside down the LED chip 200, so that the positive electrode 208 of the LED is aligned to the positive electrode 126 of the silicon sub-mount 100, the negative electrode 206 of the LED is aligned to the negative electrode 124 of the silicon sub-mount 100, then forms a hybrid packaging module by thermal bonding. The negative solder bump 116, positive solder bump 118 of the silicon sub-mount can be packaged on the PC board by flip-chip bonding. The light 302 emitted from the LED will transmit through the transparent substrate 602. The light 304 transmit to the reflection metal mirror 130 will reflect out to enhance the brightness. FIG. 3 (B) is the relative position between the positive and negative metal electrodes of the silicon sub-mount and the positive and negative electrodes of the LED chip in accordance with one embodiment of the present invention. The positive electrode 124 and the negative metal electrode 126 of the silicon sub-mount are inter-digital electrodes with larger area, while the positive electrode 208 and the negative electrode 206 of the LED are inter-digital electrodes with narrower area. FIG. 3 (C) is the relative position between the positive and negative metal electrodes of the silicon sub-mount and the positive and negative electrodes of the LED chip in accordance with another embodiment of the present invention. The positive electrode 124 and the negative metal electrode 126 of the silicon sub-mount are cylinder array electrodes, while the positive electrode 208 and the negative electrode 206 of the LED are inter-digital electrodes with narrower area.

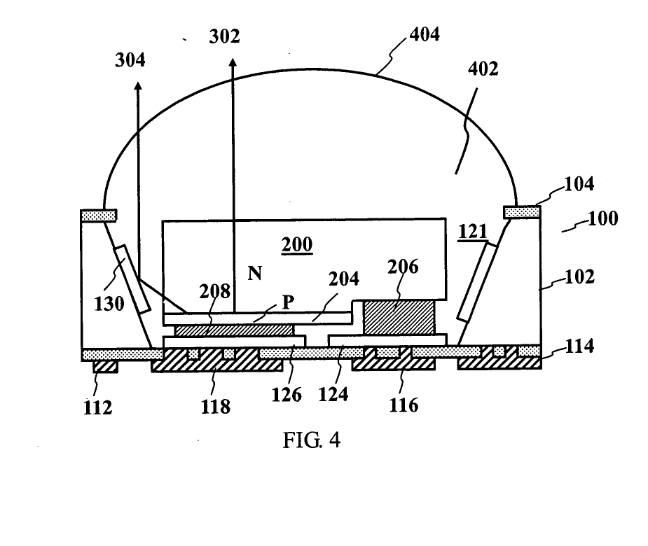

Refer to FIG. 4, FIG. 4 is a cross sectional view of forming a focus lens with transparent polymer material. Drop transparent polymer 402 into the gap of the U-shape cavity 121 to make the LED chip 200 integrates with the silicon sub-mount 100. In order to focus the light in front of the LED, the transparent polymer material forms a micro lens 404, this micro lens may be a semi-sphere or paraboroid to form a focus lens, such that the light may be focused and transmit forwardly. Finally, scribe the 300 μm of the transparent substrate 602, the silicon nitride 104 on the front side and the rear side, the negative solder bumps 116 and positive solder bumps 118 on the rear side by a scriber to cut the wafer into chips.

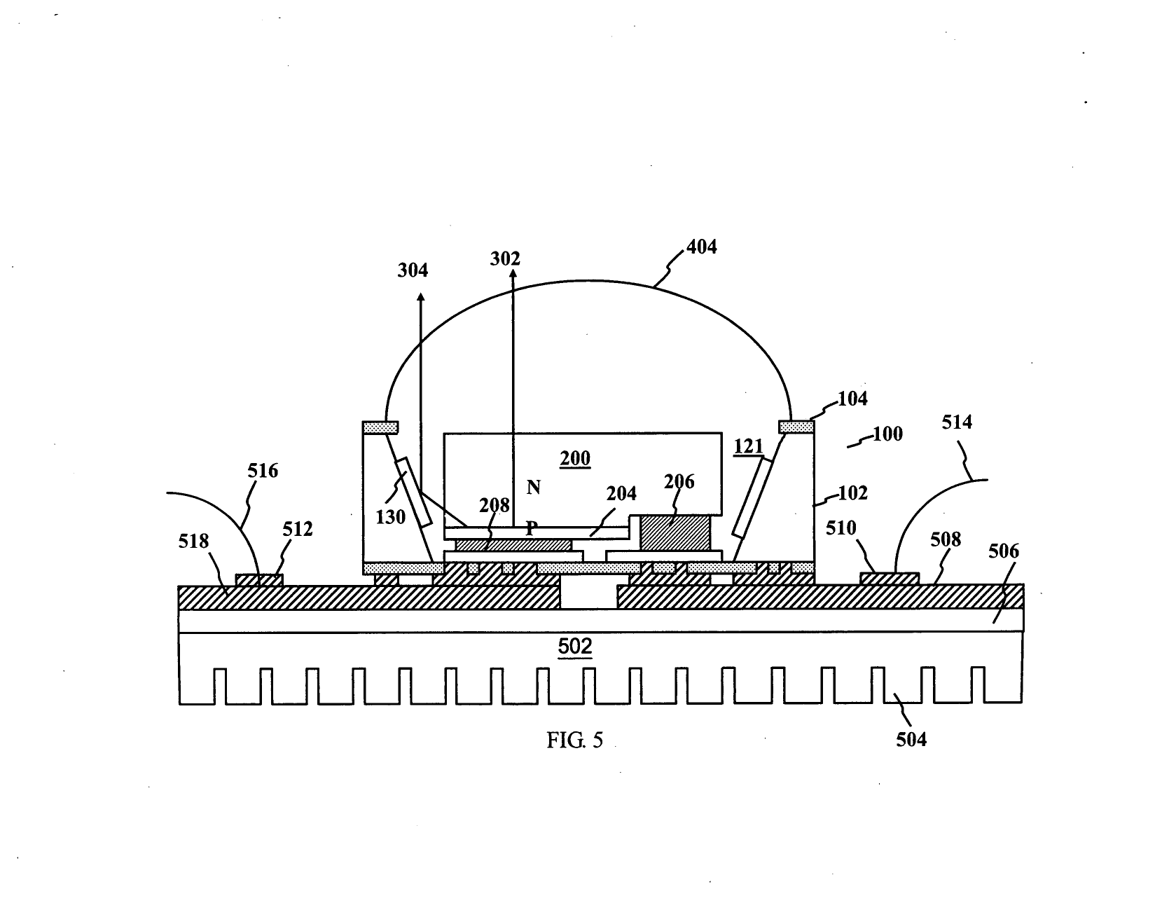

Refer to FIG. 5, FIG. 5 is a cross sectional view of flip-chip bonding the module of the LED chip and the silicon sub-mount to an aluminum PC board. Aluminum PC board is used in this years for its advantage of good heat transfer. An aluminum PC board 502 with a layer of native aluminum oxide 506 formed natively or by anodic treatment to be an isolation layer. Then forming printed circuits on the native aluminum oxide 506, such as positive electrode circuit 508, negative electrode circuit 518, both are thick film copper circuit. There are heat sink device on the back side of the aluminum PC board 502, such as multiple of extended fins 504. The solder bump 118 and 116 of the module of the LED chip 200 and the silicon sub-mount 100 is then clip-chip bonding to the positive electrode circuit 508 and the negative electrode circuit 518 of the aluminum PC board 502, the positive and negative electrodes are connected to the positive and negative electric source (not shown) of the control circuit (not shown) by bonding pads 510 and 512, bonding wires 514 and 516. LED is then emitting light under control. Since the distance from the PN junction to the heat sink is very short, it results very good heat transfer, and endure more current as compare to the conventional package without significantly temperature rising. Thus increases the light intensity.

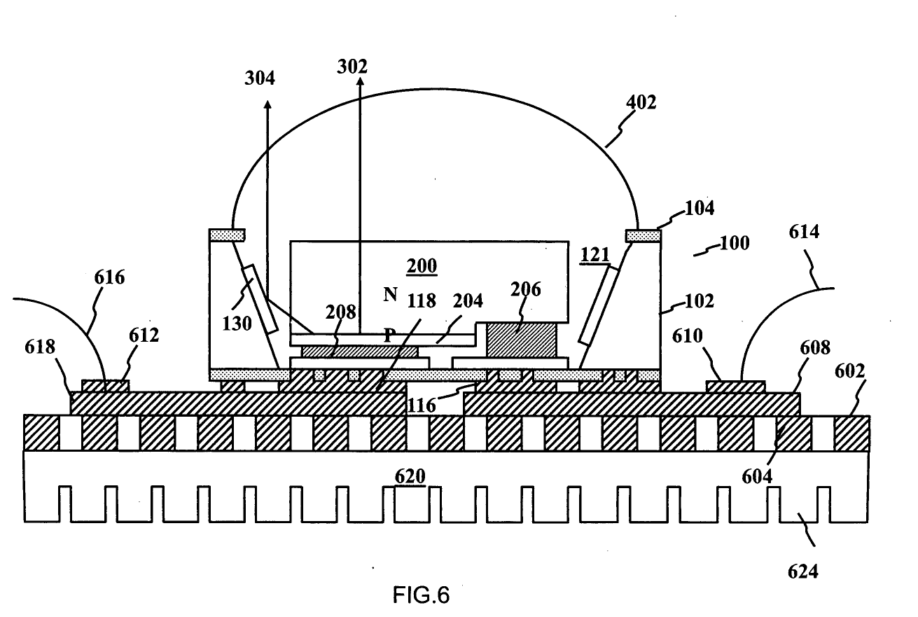

Refer to FIG. 6, FIG. 6 is a cross sectional view of flip-chip bonding the module of the LED chip and the silicon sub-mount to an ordinary PC board. The module is packaging on an ordinary PC board 602 with metal via holes 604 on. The solder bump 118 and 116 of the module of the LED chip 200 and the silicon sub-mount 100 is then flip-chip bonding to the positive electrode circuit 608 and the negative electrode circuit 618 of the aluminum PC board 602. The LED chip 200, the silicon sub-mount 100 and the PC board 602 is then bonded on the aluminum heat sink device 620. There are multiple of extended fins 624 on the aluminum heat sink device 620. The positive and negative electrodes of the PC board are connected to the positive and negative electric source (not shown) of the control circuit (not shown) by bonding pads 610 and 612, bonding wires 614 and 616. LED is then emitting light under control. The metal via holes 604 also conducts heat quickly, also results very good heat transfer, and endure more current as compare to the conventional package without significantly temperature rising. Thus increases the light intensity.

The flip-chip bonding module of the LED chip and the silicon sub-mount can also bond on a common lead frame. By using the limited ability of heat transfer, the light intensity can also be increased.

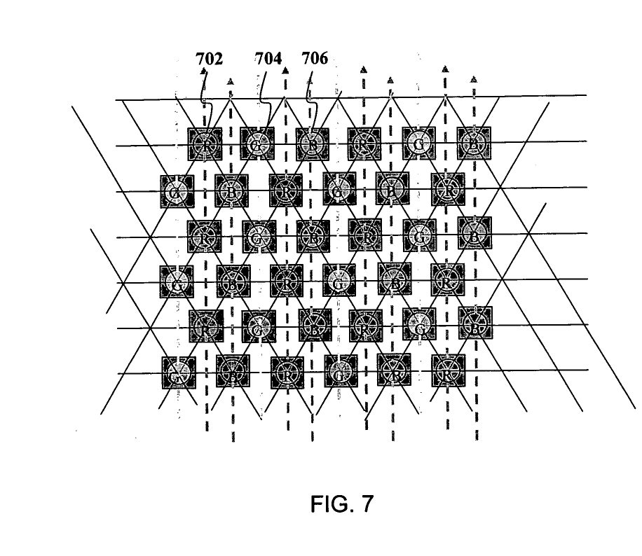

Finally, refer to FIG. 7, FIG. 7 shows the structure of a display in according to one embodiment of the present invention. Reach through U-shape cavity array is formed by etching on a silicon substrate. Then packages the red, yellow and blue LED chips 702, 704 and 706 with flip chip packaging into the U-shape cavity array to form a structure of display.

Although the present invention has been explained in relation to its preferred embodiment, it is to be understood that many other possible modifications and variations can be made without departing from the spirit and scope of the invention as hereinafter claimed.

What is claimed is:

1. A packaging structure of light emitting diode (LED), the LED chip is bonding into the U-shape cavity of a silicon sub-mount by flip-chip bonding to form a cascaded packaging module, this module is then packaged by flip-chip surface mount on an aluminum PC board with heat-sink, comprising:
a silicon sub-mount, forming solder bumps of positive and negative electrode on the front side; etching a reach-through U-shape cavity on the back-side to accommodate said LED chip, evaporating a positive electrode, a negative electrode, and reflective metals with a native mask;
a light emitting diode (LED) chip, can be any chip produced by a conventional technology; having a substrate, an active light emitting area, a positive and a negative electrode on the front-side;
a PC board, having an anodic oxide layer, a printed circuit, and a heat-sink device;
said LED chip is bonding into said silicon sub-mount by flip-chip die bonding, the positive and negative electrodes of said LED chip are aligned to the positive and negative electrodes of the silicon sub-mount, respectively, to form a cascaded packaging module;
bonding said cascaded packaging module to said PC board by flip-chip surface mount, and forms a micro lens on the surface of said LED.

2. The packaging structure as recited in claim 1, wherein said nature mask is silicon nitride (Si₃N₄).

3. The packaging structure as recited in claim 1, wherein said solder bumps of the positive and negative electrode are inter-digital electrodes.

4. The packaging structure as recited in claim 1, wherein said evaporated positive and negative electrodes are inter-digital electrodes.

5. The packaging structure as recited in claim 1, wherein said evaporated positive and negative electrodes are cylinder array electrodes.

6. The packaging structure as recited in claim 1, wherein said heat-sink device of said PC board is extended fins.

7. The packaging structure as recited in claim 1, wherein said heat-sink device of said PC board is a plane heat-sink board.

8. The packaging structure as recited in claim 1, wherein said solder bumps of the positive and negative electrodes of said silicon sub-mount is electroplating copper/tin.

9. The packaging structure as recited in claim 1, wherein said light emitted diode is a red light emitted diode.

10. The packaging structure as recited in claim 1, wherein said light emitted diode is a blue light emitted diode.

11. The packaging structure as recited in claim 1, wherein said light emitted diode is a yellow light emitted diode.

12. The packaging structure as recited in claim 1, wherein said micro lens is spherical.

13. The packaging structure as recited in claim 1, wherein said micro lens is paraboroid.

14. The packaging structure as recited in claim 1, wherein said aluminum PC board may replace by a lead frame.

15. The packaging structure as recited in claim 1, further comprising:
A reach-through U-shape cavity array is formed in a silicon substrate, and red, yellow and green LEDs are bonded into the U-shape cavity array by flip-chip packaging to form a display device.
